(19) United States
(12) Patent Application Publication
(10) Pub. No.: US 2026/0096186 A1
(43) Pub. Date: Apr. 2, 2026

(54) SEMICONDUCTOR DEVICE AND FABRICATION METHOD THEREOF

(71) Applicant: Vanguard International Semiconductor Corporation, Hsinchu (TW)

(72) Inventors: Chen-Dong Tzou, Taipei City (TW); Chia-Hao Lee, Hsinchu County (TW)

(73) Assignee: Vanguard International Semiconductor Corporation, Hsinchu (TW)

(21) Appl. No.: 18/902,834

(22) Filed: Sep. 30, 2024

(51) Int. Cl. H01L 29/78; H01L 21/8234; H01L 27/06; H01L 29/40; H01L 29/423; H01L 29/66; H01L 29/872

(52) U.S. Cl. CPC H10D 84/146; H10D 8/051; H10D 8/605; H10D 30/0297; H10D 64/117; H10D 64/519; H10D 84/0135; H10D 84/016; H10D 84/038; H10D 84/811

(57) ABSTRACT

A semiconductor device includes an epitaxial layer disposed on a substrate. The substrate includes a first region and a second region, where the first region is a drain region and the second region is a cathode. A first trench, a second trench and a third trench are disposed in the epitaxial layer. A gate includes a planar conductive portion on the epitaxial layer and a first trench conductive portion in the first trench. A source region is disposed in the epitaxial layer and on sides of the first trench. An anode is disposed on the epitaxial layer and between the second and third trenches. A first heavily doped region is disposed in the epitaxial layer and directly below the anode, and includes a first portion abutting the second trench and a second portion abutting the third trench.

### BACKGROUND OF THE INVENTION

### 1. Field of the Invention

The present disclosure relates generally to semiconductor technology, and more particularly to a semiconductor device including a trench field-effect transistor and an embedded Schottky barrier diode and a fabrication method thereof.

### 2. Description of the Prior Art

Metal-oxide-semiconductor field-effect transistors (MOSFETs) are common power transistors used in integrated circuits, and usually operated under high voltage and high current. MOSFETs may include a horizontal structure such as a laterally-diffused metal-oxide-semiconductor (LDMOS) field-effect transistor (FET), and a vertical structure such as a trench MOSFET. The trench MOSFET has a gate disposed in a trench, and the current between a source and a drain thereof flows in a vertical direction. The trench MOSFET has the advantages of decreasing the size of an element unit and reducing the parasitic capacitance. However, the conventional trench MOSFETs still cannot fully satisfy various requirements of power electronic applications, such as in the breakdown voltage, the on-state resistance and the switching loss.

### SUMMARY OF THE INVENTION

In view of this, the present disclosure provides a semiconductor device and a fabrication method thereof. The semiconductor device includes an embedded Schottky barrier diode (E-SBD) connected in parallel with a trench MOSFET. The embedded SBD improves the electrical requirements of the semiconductor device, such as in terms of breakdown voltage (BV), on-state resistance (Ron), switching power loss (Psw), etc., which is beneficial for applications operating under high-frequency electrical signals. Moreover, the formation of the embedded SBD is integrated with the processes of fabricating the trench MOSFET without additional photo-masks and process steps.

According to an embodiment of the present disclosure, a semiconductor device is provided and includes a substrate, an epitaxial layer, a first trench, a second trench, a third trench, a gate, a source region, an anode and a first heavily doped region. The substrate has a first conductivity type and includes a first region and a second region, where the first region is a drain region and the second region is a cathode. The epitaxial layer has the first conductivity type and is disposed on the substrate. The first trench, the second trench and the third trench are disposed in the epitaxial layer. The gate includes a planar conductive portion disposed on the epitaxial layer and a first trench conductive portion disposed in the first trench. The source region is disposed in the epitaxial layer and located on sides of the first trench. The anode is disposed on the epitaxial layer and located between the second trench and the third trench. The first heavily doped region has a second conductivity type, is disposed in the epitaxial layer and directly below the anode. The first heavily doped region includes a first portion and a second portion laterally separated from each other, where the first portion abuts the second trench and the second portion abuts the third trench.

According to an embodiment of the present disclosure, a method of fabricating a semiconductor device is provided and includes the following steps. A substrate having a first conductivity type is provided and includes a first region and a second region, where the first region is a drain region, and the second region is a cathode. An epitaxial layer is formed on the substrate and has the first conductivity type. A first trench, a second trench and a third trench are simultaneously formed in the epitaxial layer. The first trench, the second trench and the third trench are filled up with a conductive material to form a first trench conductive portion, a second trench conductive portion and a third trench conductive portion, respectively. A planar conductive portion is formed on the epitaxial layer, where the planar conductive portion and the first trench conductive portion constitute a gate. A source region is formed in the epitaxial layer and located on sides of the first trench. A first heavily doped region is formed in the epitaxial layer, has a second conductivity type, and includes a first portion and a second portion laterally separated from each other, where the first portion abuts the second trench and the second portion abuts the third trench. In addition, an anode is formed on the epitaxial layer, located between the second trench and the third trench, and directly above the first heavily doped region.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

Aspects of the present disclosure are best understood from the following detailed description when read with the accompanying figures. It is noted that, in accordance with the standard practice in the industry, various features may not be drawn to scale. In fact, the dimensions of the various features may be arbitrarily increased or reduced for clarity of discussion.

FIG. 1 illustrates a schematic cross-sectional view and an equivalent circuit of a semiconductor device according to an embodiment of the present disclosure.

FIG. 2 illustrates the source current-to-source voltage characteristic curves of semiconductor devices according to an embodiment of the present disclosure and a comparative example when a DC voltage is applied.

FIG. 3 illustrates the source current-to-time characteristic curves of semiconductor devices according to an embodiment of the present disclosure and a comparative example when an AC voltage is applied.

FIG. 4, FIG. 5, FIG. 6, FIG. 7 and FIG. 8 are schematic cross-sectional views of some stages of a method of fabricating a semiconductor device according to an embodiment of the present disclosure.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “under,” “lower,” “over,” “above,” “on,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. For example, if the device in the figures is turned over, elements described as “below” and/or “beneath” other elements or features would then be oriented “above” and/or “over” the other elements or features. The apparatus may be otherwise oriented (rotated 90 degrees or at other orientations) and the spatially relative descriptors used herein may likewise be interpreted accordingly.

It is understood that, although the terms first, second, third, etc. may be used herein to describe various elements, components, regions, layers and/or sections, these elements, components, regions, layers and/or sections should not be limited by these terms. These terms may be only used to distinguish one element, component, region, layer and/or section from another region, layer and/or section. Terms such as “first,” “second,” and other numerical terms when used herein do not imply a sequence or order unless clearly indicated by the context. Thus, a first element, component, region, layer and/or section discussed below could be termed a second element, component, region, layer and/or section without departing from the teachings of the embodiments.

As disclosed herein, the term “about” or “substantial” generally means within 20%, 10%, 5%, 3%, 2%, 1%, or 0.5% of a given value or range. Unless otherwise expressly specified, all of the numerical ranges, amounts, values and percentages disclosed herein should be understood as modified in all instances by the term “about” or “substantial”. Accordingly, unless indicated to the contrary, the numerical parameters set forth in the present disclosure and attached claims are approximations that can vary as desired.

Furthermore, as disclosed herein, the terms “coupled to” and “electrically connected to” include any directly and indirectly electrical connecting means. Therefore, if it is described in this document that a first component is coupled or electrically connected to a second component, it means that the first component may be directly connected to the second component, or may be indirectly connected to the second component through other components or other connecting means.

Although the disclosure is described with respect to specific embodiments, the principles of the disclosure, as defined by the claims appended herein, can obviously be applied beyond the specifically described embodiments of the disclosure described herein. Moreover, in the description of the present disclosure, certain details have been left out in order to not obscure the inventive aspects of the disclosure. The details left out are within the knowledge of a person having ordinary skill in the art.

The present disclosure relates to a semiconductor device including a trench MOSFET and an embedded SBD and a fabrication method thereof, where the embedded SBD is connected in parallel with the trench MOSFET, and both are integrated on a single chip. The embedded SBD is disposed between two trenches and integrated with the fabrication processes of the trench MOSFET. Therefore, the semiconductor device including the embedded SBD is fabricated without additional photo-masks and process steps. The embedded SBD improves the electrical performances of the semiconductor device, such as in terms of breakdown voltage, on-state resistance and switching power loss, which is beneficial for applications operating under high-frequency electrical signals.

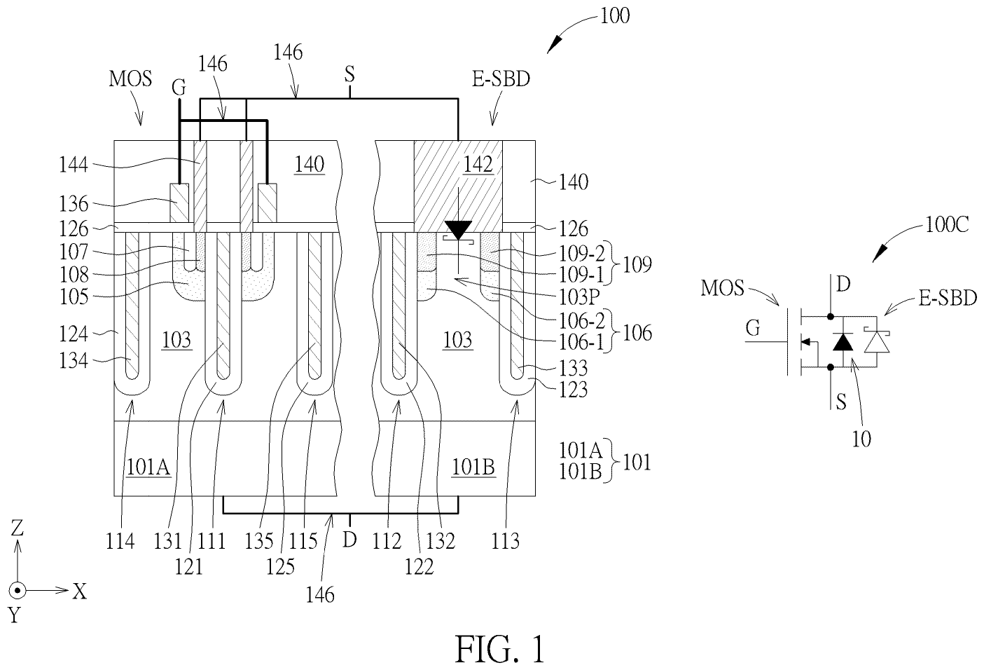

FIG. 1 shows a schematic cross-sectional view and an equivalent circuit 100C of a semiconductor device 100 according to an embodiment of the present disclosure. The semiconductor device 100 includes an embedded Schottky barrier diode (hereinafter also referred to as a Schottky barrier diode) E-SBD connected in parallel with a trench MOSFET (hereinafter also referred to as a field-effect transistor) MOS. The Schottky barrier diode E-SBD and the field-effect transistor MOS are integrated into a single chip. As shown in FIG. 1, the semiconductor device 100 includes a substrate 101 having a first conductivity type, for example, an N-type heavily doped substrate. The substrate 101 includes a first region 101A and a second region 101B, where the first region 101A is a drain region of the field-effect transistor MOS, and the second region 101B is a cathode of the Schottky barrier diode E-SBD. An epitaxial layer 103 is disposed on the substrate 101 and has the first conductivity type that is the same as the conductivity type of the substrate 101. The doping concentration of the epitaxial layer 103 is lower than that of the substrate 101. The epitaxial layer 103 is, for example, an N-type lightly doped epitaxial layer. In some embodiments, the compositions of the substrate 101 and the epitaxial layer 103 are, such as silicon, silicon carbide (SiC), aluminum nitride (AlN), gallium nitride (GaN) or other suitable semiconductor materials. The composition of the epitaxial layer 103 may be the same as or different from that of the substrate 101.

The semiconductor device 100 includes multiple trenches, such as a first trench 111, a second trench 112, a third trench 113, a fourth trench 114 and a fifth trench 115, disposed in the epitaxial layer 103. These trenches extend from the top surface of the epitaxial layer 103 downward to the same depth position. The first trench 111, the fourth trench 114 and the fifth trench 115 are located in the area of the field-effect transistor MOS. The first trench 111 is disposed between the fourth trench 114 and the fifth trench 115. The second trench 112 and the third trench 113 are located in the area of the Schottky barrier diode E-SBD. In the first trench 111, a first dielectric layer 121 surrounds a first trench conductive portion 131. In the second trench 112, a second dielectric layer 122 surrounds a second trench conductive portion 132. In the third trench 113, a third dielectric layer 123 surrounds a third trench conductive portion 133. In the fourth trench 114, a fourth dielectric layer 124 surrounds a fourth trench conductive portion 134. In the fifth trench 115, a fifth dielectric layer 125 surrounds a fifth trench conductive portion 135. In some embodiments, the first dielectric layer 121, the second dielectric layer 122, the third dielectric layer 123, the fourth dielectric layer 124 and the fifth dielectric layer 125 have the same composition, such as silicon oxide, silicon nitride, silicon oxynitride, a combination thereof, or other suitable dielectric materials, and these dielectric layers may have substantially the same thickness. The first trench conductive portion 131, the second trench conductive portion 132, the third trench conductive portion 133, the fourth trench conductive portion 134 and the fifth trench conductive portion 135 may also have the same composition, such as doped polysilicon or other suitable conductive materials.

In one embodiment, the semiconductor device 100 may include a body region 105 and a shield region 106 disposed in the epitaxial layer 103. Both the body region 105 and the shield region 106 have a second conductivity type. The body region 105 is, for example, a P-type body region (P-body), located on two sides of the first trench 111 and abuts the sides of the first trench 111. The body region 105 of the second conductivity type and the epitaxial layer 103 of the first conductive type can constitute a body diode 10. The shield region 106 is, for example, a P-type shield region (P-shield) and includes two laterally separated portions 106-1 and 106-2. The portion 106-1 (also referred to as a third portion) abuts one side of the second trench 112. The portion 106-2 (also referred to as a fourth portion) abuts one side of the third trench 113. The body region 105 and the shield region 106 may have the same doping concentration, and the bottom surfaces of the body region 105 and the shield region 106 may be at the same horizontal level. In another embodiment, the semiconductor device 100 includes the body region 105 and does not include the shield region 106. The shield region 106 is optionally disposed in the semiconductor device 100.

A source region 107 of the field-effect transistor MOS has the first conductivity type, for example, an N-type heavily doped region. The source region 107 is disposed in the epitaxial layer 103 and located in the body region 105. In one embodiment, the source region 107 is disposed on two sides of the first trench 111. The semiconductor device 100 further includes a first heavily doped region 109 and a second heavily doped region 108 disposed in the epitaxial layer 103 and both have the second conductivity type, for example, P-type heavily doped regions. The doping concentration of the first heavily doped region 109 is higher than that of the shield region 106, and the doping concentration of the second heavily doped region 108 is higher than that of the body region 105. The first heavily doped region 109 is located in the area of the Schottky barrier diode E-SBD, and includes a first portion 109-1 laterally separated from a second portion 109-2. The first portion 109-1 abuts one side of the second trench 112, and the second portion 109-2 abuts one side of the third trench 113. The first portion 109-1 is located directly above the third portion 106-1 of the shield region 106, and the second portion 109-2 is located directly above the fourth portion 106-2 of the shield region 106. The second heavily doped region 108 is located in the area of the field-effect transistor MOS, disposed in the body region 105 and between the source region 107 and the first trench 111. In one embodiment, the second heavily doped region 108 may be disposed on and abut two sides of the first trench 111. The first heavily doped region 109 and the second heavily doped region 108 may have the same doping concentration, and the bottom surfaces of the first heavily doped region 109 and the second heavily doped region 108 may be at the same horizontal level.

As shown in FIG. 1, an anode 142 of the Schottky barrier diode E-SBD is disposed on the epitaxial layer 103 and between the second trench 112 and the third trench 113. The first heavily doped region 109 and a portion 103P of the epitaxial layer 103 are disposed directly below the anode 142, and the portion 103P of the epitaxial layer 103 is located between the first portion 109-1 and the second portion 109-2 of the first heavily doped region 109. The anode 142 is in direct contact with the portion 103P of the epitaxial layer 103 to constitute the embedded Schottky barrier diode E-SBD. The composition of the anode 142 is metal or other conductive materials that can produce Schottky contact with the semiconductor material of the epitaxial layer 103. In some embodiments, the composition of the anode 142 may be a refractory metal, compounds or silicides of the refractory metal, such as tantalum (Ta), tantalum nitride (TaN), titanium nitride (TiN), tungsten (W), tungsten silicide (WSi₂), nickel (Ni), gold (Au), platinum (Pt), alloy, or a stack thereof. Moreover, the anode 142 may be composed of doped polysilicon.

The semiconductor device 100 further includes a planar conductive portion 136 disposed on the epitaxial layer 103 and directly above the body region 105. The planar conductive portion 136 and the first trench conductive portion 131 constitute a gate of the field-effect transistor MOS. The field-effect transistor MOS has a planar split gate trench (planar SGT) structure and has both horizontal and vertical channels. The upper portion of the first trench conductive portion 131 is used as the gate, and the lower portion thereof may be used as a field plate. In addition, a gate dielectric layer 126 is disposed between the epitaxial layer 103 and the planar conductive portion 136. In some embodiments, the composition of the planar conductive portion 136 is, for example, polysilicon or other suitable conductive materials. The composition of the gate dielectric layer 126 is, for example, silicon oxide, silicon nitride, silicon oxynitride, or a combination thereof.

In addition, a source contact 144 is disposed on the epitaxial layer 103 and electrically connected to the source region 107 and the second heavily doped region 108. As shown in FIG. 1, an interlayer dielectric (ILD) layer 140 is disposed on the gate dielectric layer 126. The source contact 144 penetrates the ILD layer 140 and the gate dielectric layer 126 to contact the second heavily doped region 108 and the source region 107. Furthermore, the anode 142 also penetrates the ILD layer 140 and the gate dielectric layer 126 to contact the portion 103P of the epitaxial layer 103 and the first heavily doped region 109. When viewed from top, the first portion 109-1 and the second portion 109-2 of the first heavily doped region 109 overlap with the peripheral area of the anode 142, and the portion 103P of the epitaxial layer 103 overlaps with the central area of the anode 142. The first heavily doped region 109 and the shield region 106 located in the peripheral area of the anode 142 can reduce the surface electric field and suppress the leakage current of the Schottky barrier diode E-SBD.

Referring to the cross-sectional view and the equivalent circuit 100C of the semiconductor device 100 in FIG. 1, the Schottky barrier diode E-SBD is connected in parallel with the field-effect transistor MOS. The anode 142 of the Schottky barrier diode E-SBD and the source region 107 of the field-effect transistor MOS are both electrically coupled to a source terminal S. The second region 101B (the cathode) of the Schottky barrier diode E-SBD and the first region 101A (the drain region) of the field-effect-transistor MOS are both electrically coupled to a drain terminal D. Since the Schottky barrier diode E-SBD is connected in parallel with the field-effect transistor MOS, the Schottky barrier diode E-SBD will not affect the on-state resistance (Ron, sp) of the field-effect transistor MOS.

Moreover, in one embodiment, the second trench conductive portion 132 and the third trench conductive portion 133 of the Schottky barrier diode E-SBD are both electrically connected to the anode 142. The planar conductive portion 136, the first trench conductive portion 131, the fourth trench conductive portion 134 and the fifth trench conductive portion 135 of the field-effect transistor MOS are all electrically coupled to a gate terminal G. In another embodiment, the planar conductive portion 136, the first trench conductive portion 131, the fourth trench conductive portion 134 and the fifth trench conductive portion 135 of the field-effect transistor MOS, and the second trench conductive portion 132 and the third trench conductive portion 133 of the Schottky barrier diode E-SBD are all electrically coupled to the gate terminal G. Through the arrangement of the second trench conductive portion 132 and the third trench conductive portion 133, the breakdown voltage of the Schottky barrier diode E-SBD is enhanced to be higher than the breakdown voltage of the field-effect transistor MOS. This ensures that the Schottky barrier diode E-SBD connected in parallel with the field-effect transistor MOS does not become a weak point in the circuit, and the area where electrical collapse occurs is confined to the cell region of the field-effect transistor MOS.

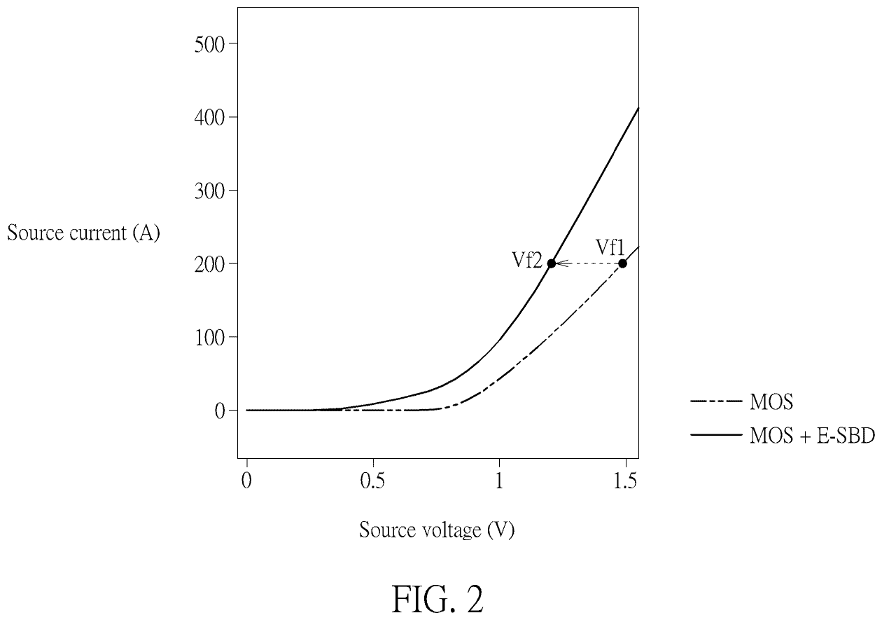

FIG. 2 illustrates the source current-to-source voltage characteristic curves of semiconductor devices according to an embodiment of the present disclosure and a comparative example when a direct current (DC) is applied. The embodiment MOS+E-SBD is, for example, the semiconductor device 100 of FIG. 1 that includes the Schottky barrier diode E-SBD connected in parallel with the field-effect transistor MOS. The comparative example MOS is a semiconductor device without the Schottky barrier diode E-SBD of FIG. 1 and only has the field-effect transistor MOS of FIG. 1. The horizontal axis of FIG. 2 is the source voltage in volts (V), and the vertical axis of FIG. 2 is the source current in amperes (A). As shown in FIG. 2, in the semiconductor device of the comparative example MOS, when the source voltage is 0.7V to 1.5V, the field-effect transistor MOS is turned on. In the semiconductor device of the embodiment MOS+E-SBD, when the source voltage is 0.3V to 0.7V, the Schottky barrier diode E-SBD is turned on, and when the source voltage is 0.7V to 1.5V, the field-effect transistor MOS is turned on. In addition, when the source current is 200A, the forward voltage drop Vf1 of the semiconductor device of the comparative example MOS is about 1.48V, and the forward voltage drop Vf2 of the semiconductor device of the embodiment MOS+E-SBD is about 1.20V. Compared with the semiconductor device of the comparative example MOS, the forward voltage drop (Vf) of the semiconductor device of the embodiment MOS+E-SBD is reduced by about 19%. This means that according to the embodiment of the present disclosure, the semiconductor device including the Schott barrier diode E-SBD and the field-effect transistor MOS can reduce the forward voltage drop, thereby reducing the power loss in the on-state.

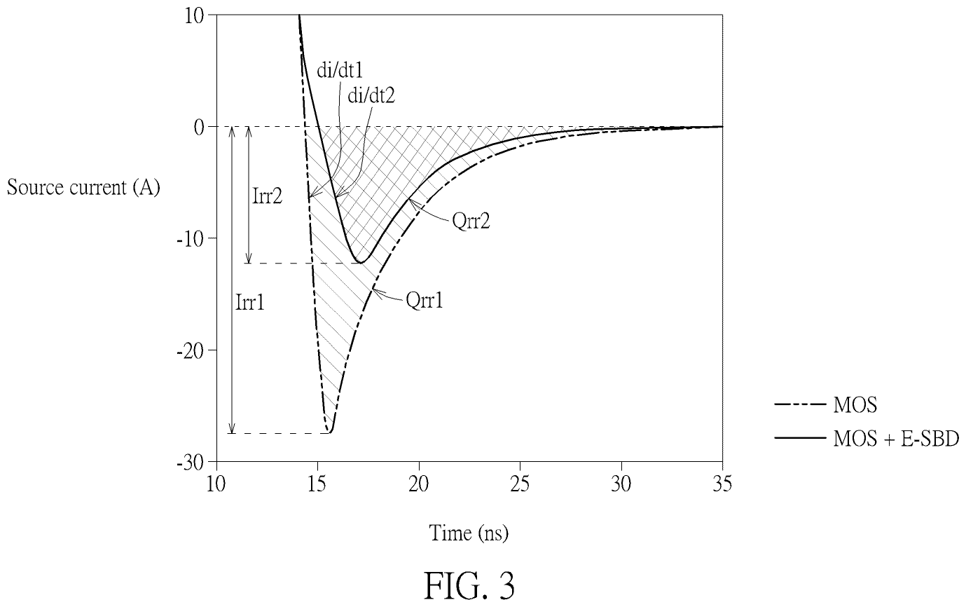

FIG. 3 illustrates the source current-to-time characteristic curves of semiconductor devices according to an embodiment of the present disclosure and a comparative example when an alternating current (AC) is applied. The embodiment MOS+E-SBD and the comparative example MOS may refer to the aforementioned descriptions of FIG. 2. The horizontal axis of FIG. 3 is the time in nanoseconds (ns), and the vertical axis of FIG. 3 is the source current in amperes (A). When the source current is below \textcircled{0}A, the integrated area of the characteristic curve to the time is the reverse recovered charge (Qrr). When the source current is below \textcircled{0}A, the maximum current is the reverse recovered current peak (Irr, peak). The rate of change of the source current per unit of time is di/dt.

As shown in FIG. 3, the reverse recovery charge Qrr1 of the comparative example MOS is about 104.99 nanocoulombs (nC), and the reverse recovery charge Qrr2 of the embodiment MOS+E-SBD is about 53.29 nC. Compared with the reverse recovery charge Qrr1 of the comparative example MOS, the reverse recovery charge Qrr2 of the embodiment MOS+E-SBD is reduced by about 49%. In addition, the reverse recovery current peak Irr1 of the comparative example MOS is about 27.55 amperes (A), and the reverse recovery current peak Irr2 of the embodiment MOS+E-SBD is about 12.26 A. Compared with the reverse recovery current peak Irr1 of the comparative example MOS, the reverse recovery current peak Irr2 of the embodiment MOS+E-SBD is reduced by about 56%. Moreover, the current change rate di/dt1 of the comparative example MOS is about 22.96 amperes/nanoseconds (A/ns), and the current change rate di/dt2 of the embodiment MOS+E-SBD is about 6.13 A/ns. Compared with the current change rate di/dt1 of the comparative example MOS, the current change rate di/dt2 of the embodiment MOS+E-SBD is reduced by about 73%.

From the characteristic curves of FIG. 2 and FIG. 3, it is known that compared with the semiconductor device of the comparative example MOS, the forward voltage drop (Vf), the reverse recovery charge (Qrr), the reverse recovery current (Irr) and the current change rate (di/dt) of the semiconductor device of the embodiment MOS+E-SBD have been significantly improved. This means that by disposing a unipolar element of the Schottky barrier diode E-SBD in the semiconductor device according to the embodiments of the present disclosure, the conduction loss and the switching power loss (Psw) are both reduced, which is beneficial for applications operating under high-frequency electrical signals.

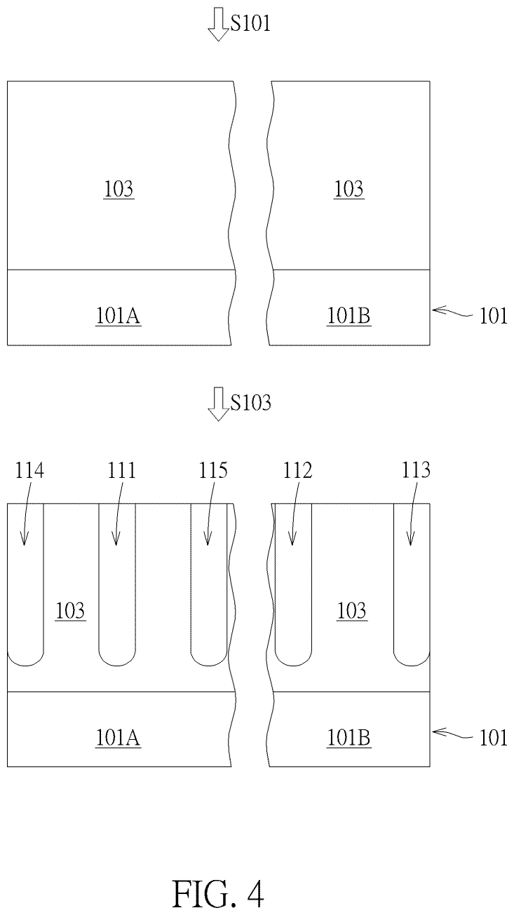

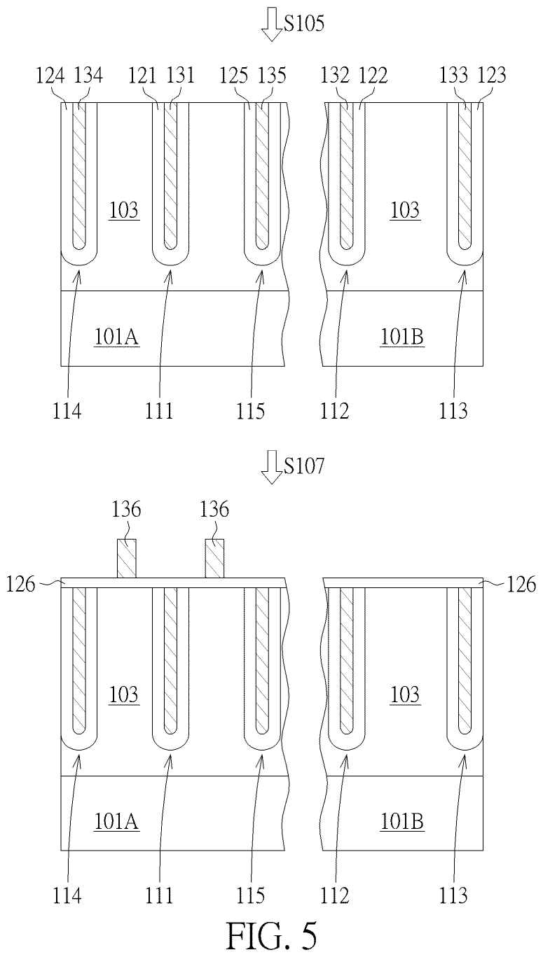

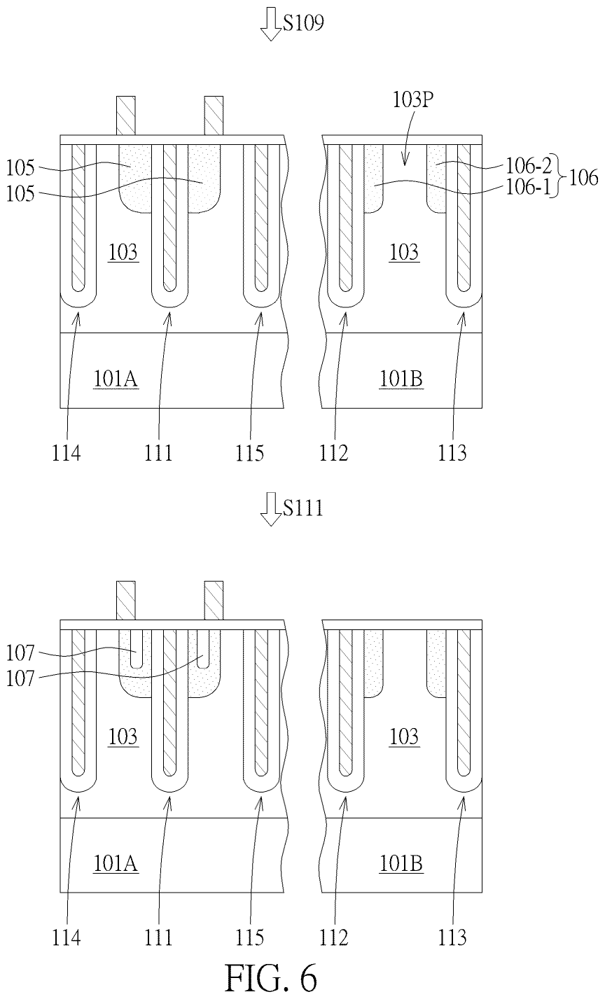

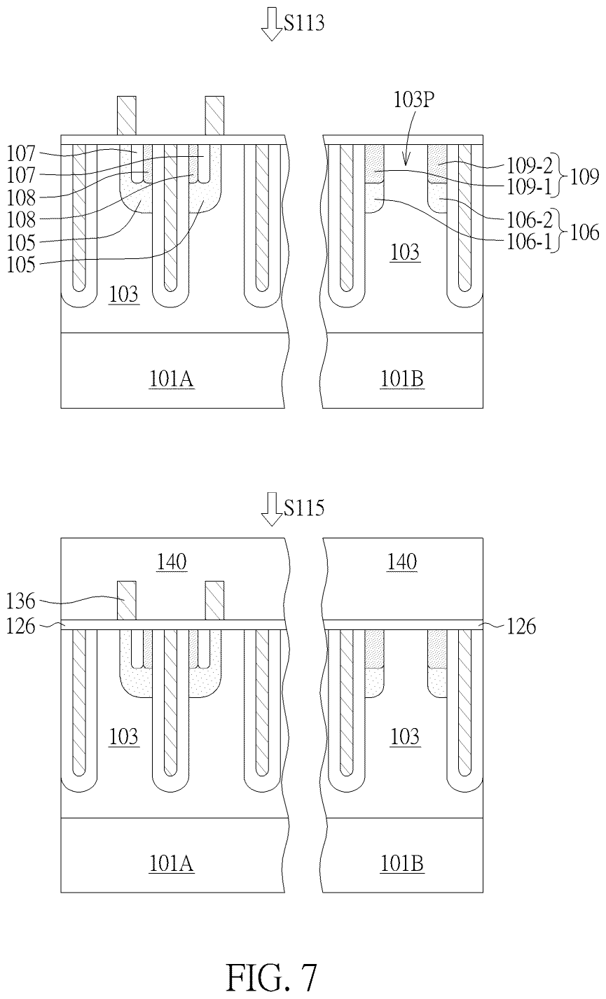

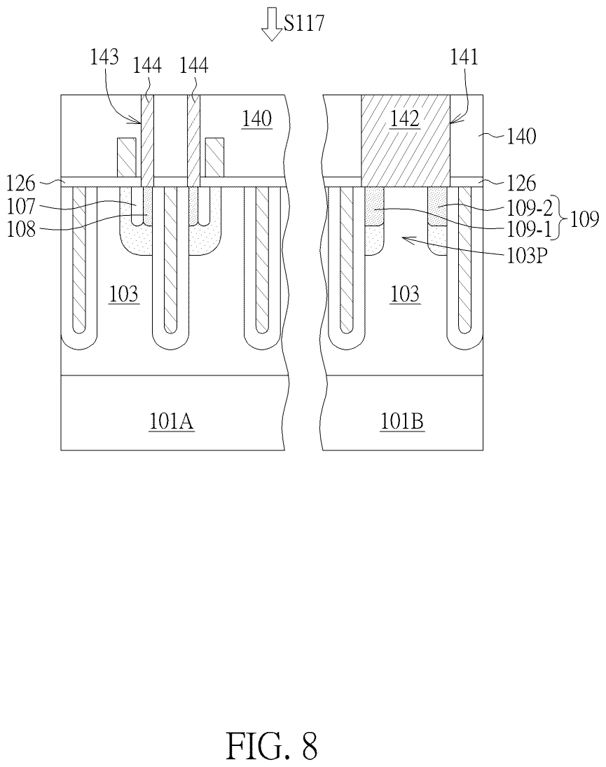

FIG. 4, FIG. 5, FIG. 6, FIG. 7 and FIG. 8 are schematic cross-sectional views of some stages of a method of fabricating a semiconductor device according to an embodiment of the present disclosure. Referring to FIG. 4, in step S101, firstly, a substrate 101 is provided and has a first conductivity type, for example, an N-type heavily doped semiconductor substrate. The substrate 101 includes a first region 101A and a second region 101B. Referring to FIG. 1, the first region 101A is the drain region of the field-effect transistor MOS, and the second region 101B is the cathode of the Schottky barrier diode E-SBD. In some embodiments, the first region 101A and the second region 101B of the substrate 101 may be arranged in various planar layouts, such as strip blocks, a check pattern, a cross grid, a donut pattern, a mixed cell, etc., thereby complying with the requirements for the electrical performances and the safe operating area (SOA) of the semiconductor devices. Then, an epitaxial layer 103 is formed on the substrate 101 by an epitaxial growth process. The dopants with the first conductivity type are added during the epitaxial growth process, thereby forming the epitaxial layer 103 with the first conductivity type, for example, an N-type lightly doped epitaxial layer.

Still referring to FIG. 4, in step S103, multiple trenches including a first trench 111, a second trench 112, a third trench 113, a fourth trench 114 and a fifth trench 115 are simultaneously formed in the epitaxial layer 103 by using a mask and an etching process. The first trench 111, the fourth trench 114 and the fifth trench 115 are located directly above the first region 101A, where the first trench 111 is located between the fourth trench 114 and the fifth trench 115. The second trench 112 and the third trench 113 are located directly above the second region 101B. The aforementioned trenches all extend from the top surface of the epitaxial layer 103 downward to substantially the same depth, such that the bottom surfaces of these trenches are at substantially the same horizontal level.

Next, referring to FIG. 5, in step S105, a dielectric material layer such as a silicon oxide layer is conformally formed in these trenches and on the top surface of the epitaxial layer 103 by a deposition process. Then, these trenches are filled up with a conductive material such as polysilicon by another deposition process. Afterwards, the dielectric material layer and the conductive material deposited on the top surface of the epitaxial layer 103 are removed by a chemical mechanical planarization (CMP) process, thereby simultaneously forming a first dielectric layer 121 in the first trench 111 to surround a first trench conductive portion 131, a second dielectric layer 122 in the second trench 112 to surround a second trench conductive portion 132, a third dielectric layer 123 in the third trench 113 to surround a third trench conductive portion 133, a fourth dielectric layer 124 in the fourth trench 114 to surround a fourth trench conductive portion 134, and a fifth dielectric layer 125 in the fifth trench 115 to surround a fifth trench conductive portion 135. The dielectric layers in these trenches may have the same composition and substantially the same thickness. The trench conductive portions in these trenches may have the same composition. The top surfaces of the dielectric layers and the top surfaces of the trench conductive portions in these trenches are on the same plane as the top surface of the epitaxial layer 103.

Still referring to FIG. 5, in step S107, a gate dielectric layer 126 is blanketly formed on the epitaxial layer 103 by deposition or thermal oxidation process. The composition of the gate dielectric layer 126 is, for example, silicon oxide. Then, a planar conductive portion 136 is formed on the gate dielectric layer 126 and directly above the first region 101A by deposition and patterning processes. The composition of the planar conductive portion 136 is, for example, polysilicon. In one embodiment, the planar conductive portion 136 is located between the first trench 111 and the fourth trench 114 and also between the first trench 111 and the fifth trench 115. The planar conductive portion 136 and the first trench conductive portion 131 constitute the gate of the field-effect transistor MOS.

Next, referring to FIG. 6, in step S109, a body region 105 and a shield region 106 are simultaneously formed in the epitaxial layer 103 by an ion implantation process. The body region 105 is located directly above the first region 101A, and the shield region 106 is located directly above the second region 101B. The body region 105 and the shield region 106 both have a second conductivity type, for example, a P-type body region (P-body) and a P-type shield region (P-shield). In one embodiment, the body region 105 abuts two sides of the first trench 111. The shield region 106 includes two laterally separated portions 106-1 and 106-2. The portion 106-1 (also referred to as a third portion) abuts the right side of the second trench 112. The portion 106-2 (also referred to as a fourth portion) abuts the left side of the third trench 113. A portion 103P of the epitaxial layer 103 is located between the two portions 106-1 and 106-2 of the shield region 106.

Still referring to FIG. 6, in step S111, a source region 107 is formed in the body region 105 by using a mask and an ion implantation process. The source region 107 has the first conductivity type, for example, an N-type heavily doped region (N⁺). The source region 107 is formed in the epitaxial layer 103 and directly above the first region 101A. Moreover, the source region 107 is located on two sides of the first trench 111, and not in contact with the sides of the first trench 111.

Next, referring to FIG. 7, in step S113, a first heavily doped region 109 is formed in the shield region 106 and a second heavily doped region 108 is formed in the body region 105 at the same time by using a mask and an ion implantation process. The first heavily doped region 109 includes a first portion 109-1 and a second portion 109-2 laterally separated from each other. The first portion 109-1 abuts one side of the second trench 112, and the second portion 109-2 abuts one side of the third trench 113. Moreover, the first portion 109-1 and the second portion 109-2 are located directly above the two portions 106-1 and 106-2 of the shield region 106, respectively. The portion 103P of the epitaxial layer 103 is located between the first portion 109-1 and the second portion 109-2 of the first heavily doped region 109. The second heavily doped region 108 is located between the source region 107 and the first trench 111. The second heavily doped region 108 may abut the sides of both the source region 107 and the first trench 111. The first heavily doped region 109 and the second heavily doped region 108 both have the second conductivity type, and are for example, P-type heavily doped regions (P⁺). Moreover, the first heavily doped region 109 and the second heavily doped region 108 have the same doping concentration, and the bottom surfaces of the first heavily doped region 109 and the second heavily doped region 108 may be at the same horizontal level. In addition, the doping concentration of the first heavily doped region 109 is higher than that of the shield region 106, and the doping concentration of the second heavily doped region 108 is higher than that of the body region 105.

Still referring to FIG. 7, in step S115, an interlayer dielectric (ILD) layer 140 is formed on the epitaxial layer 103 by a deposition process to cover the planar conductive portion 136 and the gate dielectric layer 126.

Next, referring to FIG. 8, in step S117, several openings 141 and 143 are formed in both the ILD layer 140 and the gate dielectric layer 126 by using a mask and an etching process. The portion 103P of the epitaxial layer 103 and the first heavily doped region 109 are exposed by the opening 141, and the second heavily doped region 108 and the source region 107 are exposed by the opening 143. Afterwards, the openings 141 and 143 are filled up with a conductive material by a deposition process, and then the conductive material on the ILD layer 140 is removed by a CMP process to form an anode 142 and a source contact 144. The conductive material in the openings 141 and 143 may be metal or other conductive materials that can produce Schottky contact with the semiconductor material of the epitaxial layer 103, such as refractory metal, metal silicide or doped polysilicon. As shown in FIG. 8, the anode 142 is formed on the epitaxial layer 103, between the second trench 112 and the third trench 113, and directly above the first heavily doped region 109. The anode 142 is in direct contact with the portion 103P of the epitaxial layer 103, thereby constituting the Schottky barrier diode. The source contact 144 is formed on the epitaxial layer 103 and electrically connected to the source region 107 and the second heavily doped region 108. In addition, the gate composed of the planar conductive portion 136 and the first trench conductive portion 131, the source region 107, and the drain region (the first region 101A of the substrate 101) together constitute the field-effect transistor.

Afterwards, referring to FIG. 1, an interconnection structure 146 is formed on the ILD layer 140. The anode 142 of the Schottky barrier diode E-SBD and the source contact 144 of the field-effect transistor MOS are electrically connected to the source terminal S through the interconnection structure 146. The source region 107 and the second heavily doped region 108 are also electrically coupled to the source terminal S. In addition, the cathode (the second region 101B of the substrate 101) of the Schottky barrier diode E-SBD and the drain region (the first region 101A of the substrate 101) of the field-effect transistor MOS are electrically coupled to the drain terminal D through the interconnection structure 146. The interconnection structure 146 positioned under the substrate 101 in FIG. 1 is actually formed on the ILD layer 140, and includes multiple vias (not shown) penetrating the substrate 101, the epitaxial layer 103, the gate dielectric layer 126 and the ILD layer 140 and multiple wires (not shown).

In addition, in one embodiment, both the second trench conductive portion 132 and the third trench conductive portion 133 are electrically connected to the anode 142 through multiple vias (not shown) in the ILD layer 140 and multiple wires (not shown) on the ILD layer 140. The planar conductive portion 136, the first trench conductive portion 131, the fourth trench conductive portion 134 and the fifth trench conductive portion 135 of the field-effect transistor MOS are all electrically coupled to the gate terminal G through multiple vias (not shown) in the ILD layer 140, multiple wires (not shown) on the ILD layer 140 and the interconnection structure 146. In another embodiment, the planar conductive portion 136, the first trench conductive portion 131, the fourth trench conductive portion 134 and the fifth trench conductive portion 135 of the field-effect transistor MOS, and the second trench conductive portion 132 and the third trench conductive portion 133 of the Schottky barrier diode E-SBD are all electrically coupled to the gate terminal G through multiple vias (not shown) in the ILD layer 140, multiple wires (not shown) on the ILD layer 140 and the interconnection structure 146.

According to the embodiments of the present disclosure, the semiconductor device includes an embedded Schottky barrier diode (SBD) connected in parallel with a body diode and a trench MOSFET. Since the embedded SBD is a unipolar element, compared with the body diode, the embedded SBD can produce a larger forward current under the same forward bias. According to the embodiments of the present disclosure, the semiconductor device can reduce the forward voltage drop (Vf), the reverse recovery charge (Qrr), the reverse recovery current (Irr), the reverse recovery current peak (Irr, peak), and the current change rate (di/dt), thereby significantly reducing the conduction loss and the switching power loss (Psw) of the semiconductor device. This is beneficial for applications operating under high-frequency electrical signals. Moreover, the breakdown voltage (BV) of the embedded SBD is higher than that of the trench MOSFET, so that the embedded SBD will not affect the on-state resistance (Ron) of the trench MOSFET when connected in parallel. In addition, the embedded SBD and the trench MOSFET are integrated into a single chip, thereby reducing the parasitic inductance caused by wire bonding and also reducing the footprint of the chip. Furthermore, according to the embodiments of the present disclosure, the formation of the embedded SBD is integrated with the processes of fabricating the trench MOSFET without additional photo-masks and process steps, thereby saving the cost of fabricating the semiconductor device.

Those skilled in the art will readily observe that numerous modifications and alterations of the device and method may be made while retaining the teachings of the invention.

Accordingly, the above disclosure should be construed as limited only by the metes and bounds of the appended claims.

What is claimed is:

1. A semiconductor device, comprising:
a substrate, having a first conductivity type and comprising a first region and a second region, wherein the first region is a drain region and the second region is a cathode;
an epitaxial layer, having the first conductivity type and disposed on the substrate;
a first trench, a second trench and a third trench, disposed in the epitaxial layer;
a gate, comprising a planar conductive portion disposed on the epitaxial layer and a first trench conductive portion disposed in the first trench;
a source region, disposed in the epitaxial layer and located on a side of the first trench;
an anode, disposed on the epitaxial layer and between the second trench and the third trench; and
a first heavily doped region, having a second conductivity type, disposed in the epitaxial layer, located directly below the anode, and comprising a first portion and a second portion laterally separated from each other, wherein the first portion abuts the second trench and the second portion abuts the third trench.

2. The semiconductor device of claim 1, wherein a portion of the epitaxial layer is located between the first portion and the second portion of the first heavily doped region, and the anode is in direct contact with the portion of the epitaxial layer to constitute a Schottky barrier diode.

3. The semiconductor device of claim 2, wherein the gate, the source region and the drain region constitute a field-effect transistor, the Schottky barrier diode is connected in parallel with the field-effect transistor, the anode and the source region are electrically coupled to a source terminal, and the cathode and the drain region are electrically coupled to a drain terminal.

4. The semiconductor device of claim 1, further comprising:
a second trench conductive portion disposed in the second trench and a third trench conductive portion disposed in the third trench; and
a first dielectric layer disposed in the first trench to surround the first trench conductive portion, a second dielectric layer disposed in the second trench to surround the second trench conductive portion, and a third dielectric layer disposed in the third trench to surround the third trench conductive portion,
wherein the first trench conductive portion, the second trench conductive portion and the third trench conductive portion comprise the same composition.

5. The semiconductor device of claim 4, wherein the second trench conductive portion and the third trench conductive portion are electrically connected to the anode.

6. The semiconductor device of claim 4, wherein the planar conductive portion, the first trench conductive portion, the second trench conductive portion and the third trench conductive portion are all electrically coupled to a gate terminal.

7. The semiconductor device of claim 1, further comprising:
a body region, having the second conductivity type, disposed in the epitaxial layer and located on a side of the first trench, wherein the source region is disposed in the body region; and
a shield region, having the second conductivity type, disposed in the epitaxial layer and comprising a third portion and a fourth portion laterally separated from each other, wherein the third portion and the fourth portion are located directly below the first portion and the second portion of the first heavily doped region, respectively, and a doping concentration of the first heavily doped region is higher than a doping concentration of the shield region.

8. The semiconductor device of claim 7, wherein the body region and the shield region have the same doping concentration, and a bottom surface of the body region and a bottom surface of the shield region are at the same horizontal level.

9. The semiconductor device of claim 7, further comprising a gate dielectric layer disposed between the epitaxial layer and the planar conductive portion, wherein the planar conductive portion is located directly above the body region.

10. The semiconductor device of claim 7, further comprising:
a second heavily doped region, having the second conductivity type, disposed in the body region and located between the source region and the first trench, wherein a doping concentration of the second heavily doped region is higher than a doping concentration of the body region; and
a source contact, electrically connected to the source region and the second heavily doped region.

11. The semiconductor device of claim 10, wherein the first heavily doped region and the second heavily doped region have the same doping concentration, and a bottom surface of the first heavily doped region and a bottom surface of the second heavily doped region are at the same horizontal level.

12. The semiconductor device of claim 1, wherein the first heavily doped region is in direct contact with the anode, and when viewed from top, the first portion and the second portion of the first heavily doped region are overlapped with a peripheral area of the anode.

13. A method of fabricating a semiconductor device, comprising:
providing a substrate having a first conductivity type and comprising a first region and a second region, wherein the first region is a drain region and the second region is a cathode;
forming an epitaxial layer on the substrate, wherein the epitaxial layer has the first conductivity type;
simultaneously forming a first trench, a second trench and a third trench in the epitaxial layer ;
filling the first trench, the second trench and the third trench with a conductive material to form a first trench conductive portion, a second trench conductive portion and a third trench conductive portion, respectively;
forming a planar conductive portion on the epitaxial layer, wherein the planar conductive portion and the first trench conductive portion constitute a gate;
forming a source region in the epitaxial layer and located on a side of the first trench;
forming a first heavily doped region in the epitaxial layer, wherein the first heavily doped region has a second conductivity type, comprises a first portion and a second portion laterally separated from each other, the first portion abuts the second trench, and the second portion abuts the third trench; and
forming an anode on the epitaxial layer, between the second trench and the third trench, and directly above the first heavily doped region.

14. The method of claim 13, further comprising:
simultaneously forming a body region and a shield region in the epitaxial layer,
wherein the body region and the shield region have the second conductivity type, the body region abuts the first trench, the source region is formed in the body region, the shield region comprises a third portion and a fourth portion laterally separated from each other, the third portion abuts the second trench, the fourth portion abuts the third trench, the first heavily doped region is formed in the shield region, and a doping concentration of the first heavily doped region is higher than a doping concentration of the shield region.

15. The method of claim 14, wherein forming the first heavily doped region further comprises simultaneously forming a second heavily doped region having the second conductivity type, in the body region and between the source region and the first trench, and a doping concentration of the second heavily doped region is higher than a doping concentration of the body region.

16. The method of claim 15, wherein forming the anode further comprises simultaneously forming a source contact on the epitaxial layer, and the source contact is electrically connected to the source region and the second heavily doped region.

17. The method of claim 13, wherein a portion of the epitaxial layer is located between the first portion and the second portion of the first heavily doped region, and the anode is in direct contact with the portion of the epitaxial layer to constitute a Schottky barrier diode.

18. The method of claim 17, wherein the gate, the source region and the drain region constitute a field-effect transistor, the Schottky barrier diode is connected in parallel with the field-effect transistor, the anode and the source region are electrically coupled to a source terminal, and the cathode and the drain region are electrically coupled to a drain terminal.

19. The method of claim 13, wherein the second trench conductive portion and the third trench conductive portion are electrically connected to the anode.

20. The method of claim 13, wherein the planar conductive portion, the first trench conductive portion, the second trench conductive portion and the third trench conductive portion are all electrically coupled to a gate terminal.
